(19) United States
(12) Patent Application Publication
(10) Pub. No.: US 2024/0234266 A1
(43) Pub. Date: Jul. 11, 2024

(54) SEMICONDUCTOR DEVICE

(71) Applicant: FUJI ELECTRIC CO., LTD., Kawasaki-shi (JP)

(72) Inventor: Masaharu YAMAJI, Matsumoto-city (JP)

(73) Assignee: FUJI ELECTRIC CO., LTD., Kawasaki-shi (JP)

(21) Appl. No.: 18/522,852

(22) Filed: Nov. 29, 2023

(30) Foreign Application Priority Data
Jan. 11, 2023 (JP) 2023-002681

(51) Int. Cl. H01L 23/495

(52) U.S. Cl. CPC H01L 23/49575; H01L 23/49503; H01L 23/4952; H01L 23/49562; H02P 27/06

(57) ABSTRACT

A semiconductor device 100A includes drive chips 21[k], a control chip 41A including a plurality of terminals H including a voltage terminal Hc and power supply terminals Hb[k] and configured to control each of the drive chips 21[k], using a corresponding one of power supply voltages Vb[k] supplied to a corresponding one of the power supply terminals Hb[k], a die pad 63 for supplying control voltage Vcc to the voltage terminal Hc, wires Qb[k] each connected to a corresponding one of the power supply terminals Hb[k] and for supplying a corresponding one of the power supply voltages Vb[k] to a corresponding one of the power supply terminals Hb[k], and a semiconductor chip 30A used for bootstrap operation to generate the power supply voltages Vb[k] and including diodes the number of which is the same as the number of the power supply voltages Vb[k].

### TECHNICAL FIELD

The present disclosure relates to a semiconductor device.

### BACKGROUND ART

As a semiconductor device according to prior art, an intelligent power module (IPM) used as a three-phase inverter circuit configured to drive a motor, such as a three-phase motor, has been known. Bootstrap diodes (BSDs) mounted in such an IPM have a configuration in which three chips are individually arranged for each of three phases. The bootstrap diodes are used to generate power supply voltages for controlling power semiconductor elements disposed in the IPM from a predetermined control voltage.

In Patent Document 1, a configuration to use pairs of a resistance element and a diode connected in series to each other for bootstrap operation is disclosed. In Patent Document 2, a semiconductor device including a bootstrap diode and current limiting resistors and capable of preventing deterioration in precision of the resistance values of the current limiting resistors is disclosed.

In Patent Document 3, a semiconductor device that includes a bootstrap diode and a high breakdown voltage field effect transistor in a p-type semiconductor substrate and is capable of, by forming cavities in an n⁻-type buried layer in the semiconductor substrate and using the buried layer below the cavities as a drain-drift region of the high breakdown voltage n-channel MOSFET, suppressing leakage current due to holes flowing in the semiconductor substrate side when a forward bias is applied to the bootstrap diode and at the same time increasing charging current of the bootstrap capacitor and further preventing chip area from increasing is disclosed.

In Patent Document 4, a semiconductor device in which since the semiconductor device is configured to cause a depletion layer to occur in a channel of a depletion transistor by a gate potential, current when a low voltage is applied is moderately large and current when a high voltage is applied is small is disclosed.

### CITATION LIST

### Patent Literature

Patent Document 1: JP 2014-90006 A
Patent Document 2: JP 2019-192833 A
Patent Document 3: WO 2014/199608 A1
Patent Document 4: JP 2011-129628 A

### SUMMARY OF INVENTION

### Technical Problem

Recent years, while industrial equipment and household appliances have increasingly been made highly efficient as inverters have become widely used, miniaturization of a power conversion unit has been demanded. Thus, demand for reduction in the external size of the package of an IPM has increased, and reduction in mounting area through reduction in the number of components in an IPM, improvement in power density of an element, and the like has been advanced.

Among components constituting a control unit disposed in an IPM, a drive chip and BSDs configured to drive power semiconductor elements are included. The control unit including such components is likely to have a high ratio of mounting area to area of the entire IPM. Further, since when an IPM has a three-phase structure, such as a three-phase inverter, three chips of BSDs are required to be provided, eleven chips (components) are required to be provided for the entire circuit including the control unit and the power semiconductor elements.

Further, although a technology for incorporating a BSD in a drive chip has been known, the technology has a problem in that since it is required to introduce an expensive dielectric isolation technology on the drive chip side or add a control technology of FET for bootstrap using a charge pump system, a component cost increases.

An object of the present disclosure is to provide a semiconductor device capable of, while suppressing a component cost, achieving miniaturization and cost reduction.

### Solution to Problem

In order to solve the above-described problem, a semiconductor device according to one aspect of the present disclosure includes a plurality of power semiconductor elements, a control chip including a plurality of terminals including a first terminal and a plurality of second terminals and configured to control each of the plurality of power semiconductor elements, using a corresponding one of power supply voltages supplied to a corresponding one of the plurality of second terminals, a first conductor configured to supply a predetermined control voltage to the first terminal, a plurality of first wirings each connected to a corresponding one of the plurality of second terminals and configured to supply a corresponding one of the power supply voltages to a corresponding one of the plurality of second terminals, and a semiconductor chip used for bootstrap operation to generate the power supply voltages and including diodes a number of which is same as a number of the second terminals.

### Advantageous Effects of Invention

According to the one aspect of the present disclosure, it is possible to, while suppressing a component cost, achieves miniaturization and cost reduction.

### BRIEF DESCRIPTION OF DRAWINGS

FIG. 1 is a circuit diagram illustrative of an electrical configuration of a semiconductor device according to a first embodiment of the present disclosure.

FIG. 2 is a layout diagram illustrative of an arrangement of respective elements included in the semiconductor device according to the first embodiment of the present disclosure.

FIG. 3 is a layout diagram illustrative in a vicinity of a semiconductor chip and high-potential-side drive chips included in the semiconductor device in an enlarged manner according to the first embodiment of the present disclosure.

FIG. 4 is a diagram illustrative of the semiconductor chip included in the semiconductor device according to the first embodiment of the present disclosure and is a cross-sectional view of the semiconductor chip taken along the line V-V illustrated in FIG. 3.

FIG. 5 is a layout diagram illustrative of a vicinity of semiconductor chips and high-potential-side drive chips included in a semiconductor device according to a comparative example in an enlarged manner;

FIG. 6 is a circuit diagram illustrative of an electrical configuration of a semiconductor device according to a second embodiment of the present disclosure.

FIG. 7 is a layout diagram illustrative of an arrangement of respective elements included in the semiconductor device according to the second embodiment of the present disclosure.

FIG. 8 is a layout diagram illustrative of a vicinity of a semiconductor chip and high-potential-side drive chips included in the semiconductor device in an enlarged manner according to the second embodiment of the present disclosure.

FIG. 9 is a diagram illustrative of the semiconductor chip included in the semiconductor device according to the second embodiment of the present disclosure and is a cross-sectional view of the semiconductor chip taken along the line V-V illustrated in FIG. 8.

### DESCRIPTION OF EMBODIMENTS

Embodiments for embodying the present disclosure will be described with reference to the drawings. Note that in each drawing, dimensions and a scale of each element are sometimes different from those of an actual product. Further, embodiments that will be described below are exemplary embodiments that are supposed to be embodied in the case where the present disclosure is implemented. Therefore, the scope of the present disclosure is not limited to the embodiments exemplified below.

### A: First Embodiment

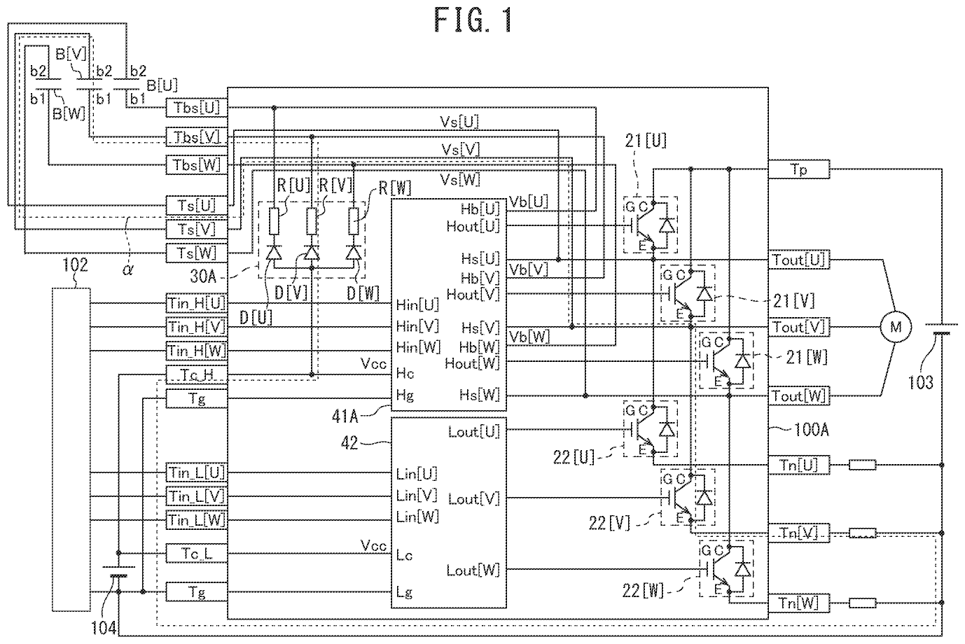

FIG. 1 is a circuit diagram illustrative of an electrical configuration of a semiconductor device 100A according to the present embodiment. The semiconductor device 100A is an intelligent power module that is used as a three-phase inverter circuit configured to drive a motor M, such as a three-phase motor. To the semiconductor device 100A, a control device 102 is connected. The control device 102 is, for example, an external micro processing unit (MPU) configured to control operation of the semiconductor device 100A.

Note that in the following description, an arbitrary AC phase in the motor M is identified by a symbol k. That is, the symbol k means any one of a U-phase, a V-phase, and a W-phase (k=U, V, or W). For example, a sign [k] appended to a reference sign means that an element indicated by the reference sign is an element corresponding to each AC phase of the motor M. As exemplarily illustrated in FIG. 1, the semiconductor device 100A includes a plurality of connection terminals T for external connections (Tin_H[k], Tin_L[k], Tout[k], Tc_H, Tc_L, Tg, Tp, Tn[k], and Tbs[k]).

The semiconductor device 100A includes three drive chips 21[k] (21[U], 21[V], and 21[W]), three drive chips 22[k] (22[U], 22[V], and 22[W]), a semiconductor chip 30A, a control chip 41A, and a control chip 42. With respect to each of the three phases (the U-phase, the V-phase, and the W-phase) of the motor M, a drive chip 21[k], a drive chip 22[k], and a semiconductor chip 30A are installed.

Each of the drive chips 21[k] and the drive chips 22[k] is a reverse conducting (RC)-insulated gate bipolar transistor (IGBT) including an IGBT and a free wheeling diode (FWD) and includes a main electrode E, a main electrode C, and a control electrode G. The main electrode E and the main electrode C are electrodes to or from which current to be controlled is input or output. The main electrode C also functions as a cathode of the FWD, and the main electrode E also functions as an anode of the FWD. The control electrode G is a gate electrode to which drive voltage for controlling ON/OFF of the IGBT is applied. Note that each of the drive chips 21[k] and the drive chips 22[k] is an example of a “power semiconductor element”. In other words, the semiconductor device 100A includes a plurality of power semiconductor elements.

Each pair of a drive chip 21[k] and a drive chip 22[k] constitutes a half-bridge circuit corresponding to one of the AC phases of the motor M. Each pair of a drive chip 21[k] and a drive chip 22[k] is connected in series between a connection terminal Tp and a corresponding one of connection terminals Tn[k]. A connection point between each pair of a drive chip 21[k] and a drive chip 22[k] is electrically connected to a corresponding one of connection terminals Tout[k]. Each of the connection terminals Tout[k] is an output terminal for supplying power to one of the AC phases of the motor M. To the connection terminal Tp, high-potential-side power supply voltage is supplied from an external power supply 103. To each of the connection terminals Tn[k], low-potential-side power supply voltage (ground voltage) is supplied. Note that the three connection terminals Tn[k] may be replaced by a single terminal common to the three phases.

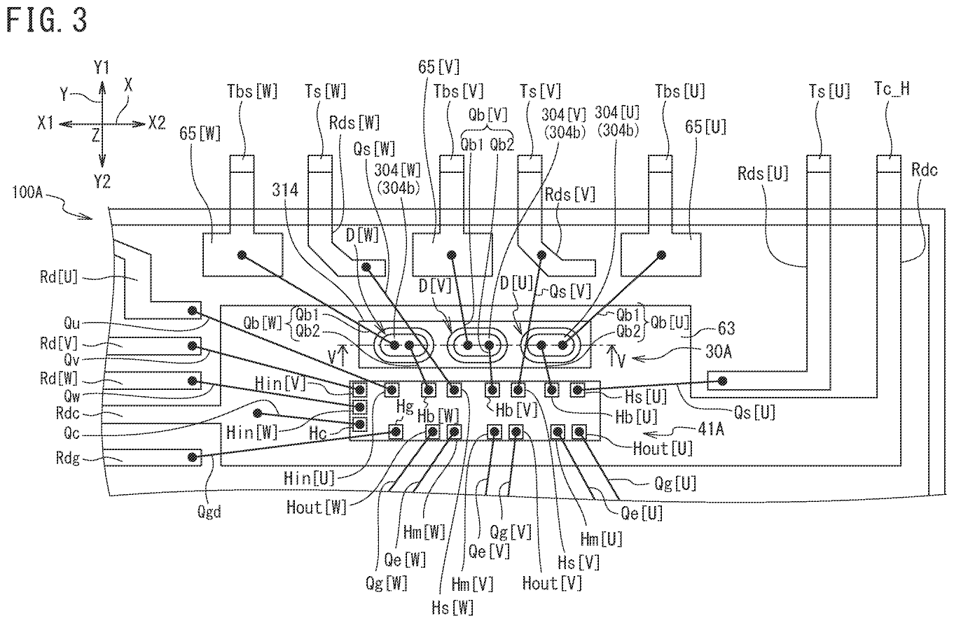

The control chip 41A is a high voltage IC (HVIC) configured to control each of the high-potential-side drive chips 21[k]. As exemplarily illustrated in FIG. 1, the control chip 41A includes a plurality of terminals H (Hin[k], Hout[k], Hb[k], Hs[k], Hm[k] (not illustrated in FIG. 1, see FIG. 3), Hc, and Hg). That is, the control chip 41A includes, with respect to each AC phase of the motor M, an input terminal Hin[k], an output terminal Hout[k], a power supply terminal Hb[k], a power supply terminal Hs[k], and a middle terminal Hm[k] (not illustrated in FIG. 1, see FIG. 3).

A control signal supplied from the control device 102 to each connection terminal Tin_H[k] is input to a corresponding one of the input terminals Hin[k]. Each of the control signals is a signal for controlling a corresponding one of the drive chips 21[k]. To each of the power supply terminals Hb[k], a corresponding one of high-potential-side power supply voltages Vb[k] is supplied, and to each of the power supply terminals Hs[k], a corresponding one of low-potential-side power supply voltages Vs[k] is supplied. The control chip 41A operates with power supply voltages supplied to the power supply terminals Hb[k] and the power supply terminals Hs[k] and thereby outputs a drive voltage matching each control signal supplied to a corresponding one of the input terminals Hin[k] to a corresponding one of the output terminals Hout[k]. Each of the output terminals Hout[k] is electrically connected to the control electrode G of the IGBT in a corresponding one of the drive chips 21[k]. As understood from the above description, the control chip 41A controls each of the drive chips 21[k], using a corresponding one of the power supply voltages Vb[k] supplied to a corresponding one of the power supply terminals Hb[k]. The power supply terminals Hb[k] are an example of “second terminals”.

Further, the control chip 41A includes a voltage terminal Hc and a ground terminal Hg. To the voltage terminal Hc, control voltage Vcc is supplied from an external power supply 104 via a connection terminal Tc_H. The control voltage Vcc is a predetermined DC voltage to be used for operation of the control chip 41A. Further, the control voltage Vcc is also used for bootstrap operations to generate the power supply voltages Vb[k] of the control chip 41A. On the other hand, the ground terminal Hg is grounded. Note that the voltage terminal Hc is an example of a “first terminal”.

Therefore, the semiconductor device 100A includes the control chip 41A including the terminals H (Hin[k], Hout[k], Hb[k], Hs[k], Hm[k], Hc, and Hg) (an example of a plurality of terminals) that includes the voltage terminal Hc (an example of the first terminal) and the power supply terminals Hb[U], Hb[V], and Hb[W] (an example of a plurality of second terminals).

The control chip 42 is a low voltage IC (LVIC) configured to control each of the low-potential-side drive chips 22[k]. Further, the control chip 41A and the control chip 42 may be formed as a single chip. As exemplarily illustrated in FIG. 1, the control chip 42 includes a plurality of terminals L (Lin[k], Lout[k], Lc, and Lg). That is, the control chip 42 includes, with respect to each AC phase of the motor M, an input terminal Lin[k], an output terminal Lout[k].

A control signal supplied from the control device 102 to each connection terminal Tin_L[k] is input to a corresponding one of the input terminals Lin[k]. Each of the control signals is a signal for controlling a corresponding one of the drive chips 22[k]. The control chip 42 outputs drive voltage matching a control signal supplied to each of the input terminals Lin[k] to a corresponding one of the output terminals Lout[k]. Each of the output terminals Lout[k] is electrically connected to the control electrode G of the IGBT in a corresponding one of the drive chips 22[k]. That is, the control chip 42 controls each of the drive chips 22[k].

Furthermore, the control chip 42 includes a voltage terminal Lc and a ground terminal Lg. To the voltage terminal Lc, the control voltage Vcc is supplied from the external power supply 104 via a connection terminal Tc_L. Note that the control voltage Vcc supplied to the control chip 41A and the control voltage Vcc supplied to the control chip 42 may differ from each other. On the other hand, the ground terminal Lg is grounded.

As exemplarily illustrated in FIG. 1, each of the power supply terminals Hb[k] of the control chip 41A is electrically connected to a corresponding one of connection terminals Tbs[k]. Between each of the connection terminals Tbs[k] and a corresponding one of connection terminals Ts[k], a capacitance element B[k] is electrically connected. Each of the capacitance elements B[k] is a bootstrap capacitor that is externally connected to the semiconductor device 100A. Each of the capacitance elements B[k] includes a first electrode b1 and a second electrode b2. The first electrode b1 is electrically connected to a corresponding one of the connection terminals Tbs[k], and the second electrode b2 is electrically connected to a corresponding one of the connection terminals Ts[k].

The semiconductor chip 30A is connected to the connection terminal Tc_H and the connection terminals Tbs[k]. That is, the semiconductor chip 30A is connected to the voltage terminal Hc and the power supply terminals Hb[k] of the control chip 41A. The semiconductor chip 30A is used for the aforementioned bootstrap operation.

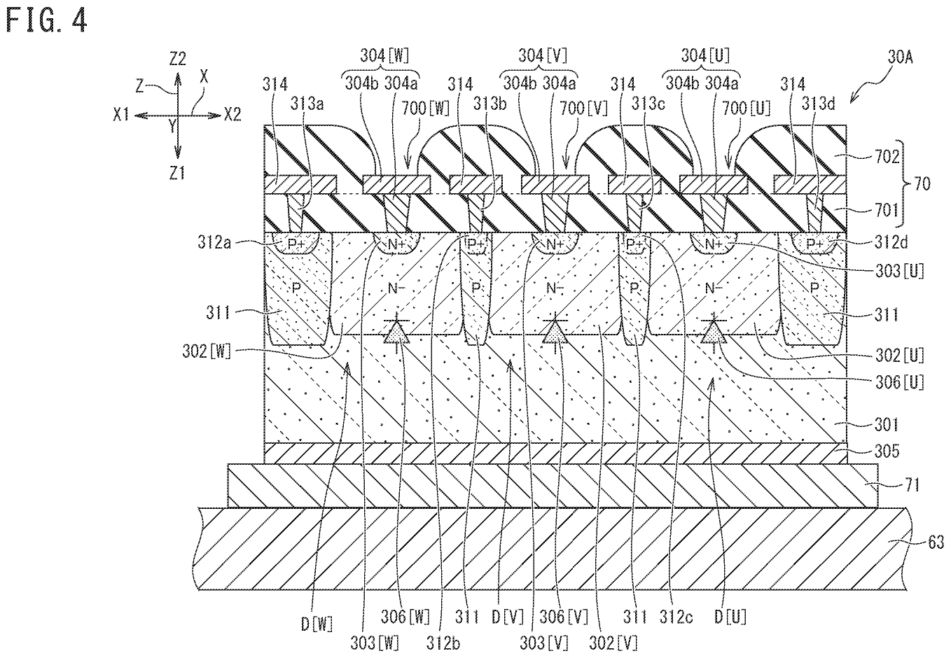

As exemplarily illustrated in FIG. 1, the semiconductor chip 30A includes diodes D[k]. Each of the diodes D[k] is a bootstrap diode that constitutes a route to charge a corresponding one of the capacitance elements B[k] (a charge route α) in the bootstrap operation. Each of the diodes D[k] includes a semiconductor substrate 301 (not illustrated in FIG. 1, see FIG. 4) and an N-diffusion layer 302[k] (not illustrated in FIG. 1, see FIG. 4) that are formed in the semiconductor chip 30A. An anode 305 (see FIG. 4) is shared by the diodes D[k], and the anode 305 is electrically connected to the connection terminal Tc_H and the voltage terminal Hc. A cathode 304[k] of each of the diodes D[k] is electrically connected to a corresponding one of the connection terminals Tbs[k] and a corresponding one of the power supply terminals Hb[k]. The semiconductor chip 30A has, on the cathode 304[k] side of each of the diodes D[k], a resistance component (drift resistance) of a corresponding one of the N⁻ diffusion layers 302[k] that is formed by the N⁻ diffusion layer 302[k] forming the diode D[k] and is connected in series with the diode D[k]. In FIG. 1, to facilitate understanding, the resistance component (drift resistance) of each of the N-diffusion layers 302[k] is illustrated as a resistance element R[k] that is disposed between the diode D[k] formed by the N⁻ diffusion layer 302[k] and a corresponding one of the connection terminals Tbs[k] and a corresponding one of the power supply terminals Hb[k]. Each of the resistance elements R[k] limits current flowing through the paired diode D[k] in the bootstrap operation. Each of the resistance elements R[k] may be, instead of the resistance component of a corresponding one of the N⁻ diffusion layers 302[k], an element that is formed of, for example, polysilicon and is connected in series with the paired diode D[k]. A detailed configuration of the semiconductor chip 30A will be described later. As described above, the semiconductor device 100A includes the semiconductor chip 30A that is used for the bootstrap operation to generate the power supply voltages Vb[k] and includes the diodes D[k] the number of which is the same (three in the present embodiment) as the number of the power supply terminals Hb[k].

In the configuration described above, controlling each of the drive chips 22[k] to the ON state while maintaining the paired drive chip 21[k] in the OFF state causes the bootstrap operation to be executed. Each of the drive chips 22[k] being controlled to the ON state causes a charge route a in FIG. 1 to be formed. Note that although, in FIG. 1, only a charge route a going through the diode D[V] disposed in the semiconductor chip 30A is illustrated for descriptive purposes, charge routes α are also likewise formed with respect to the U-phase and the W-phase.

Each of the charge routes α is a current route that goes through the connection terminal Tc_H, a corresponding one of the diodes D[k], a corresponding one of the resistance elements R[k], a corresponding one of the connection terminals Tbs[k], a corresponding one of the capacitance elements B[k], a corresponding one of the connection terminals Ts[k], a corresponding one of the drive chips 22[k], and a corresponding one of the connection terminals Tn[k] in this order. Each of the capacitance elements B[k] is charged by one of the charge routes α. Specifically, voltage across each of the capacitance elements B[k] is maintained at the control voltage Vcc due to the charging via one of the charge routes α. Therefore, each of the power supply voltages Vb[k] supplied to a corresponding one of the power supply terminals Hb[k] is set to a voltage higher than the power supply voltage Vs[k] at a corresponding one of the power supply terminals Hs[k] by the control voltage Vcc. As described above, the bootstrap operation is an operation to generate each of the power supply voltages Vb[k], using a bootstrap circuit including the semiconductor chip 30A and a corresponding one of the capacitance elements B[k].

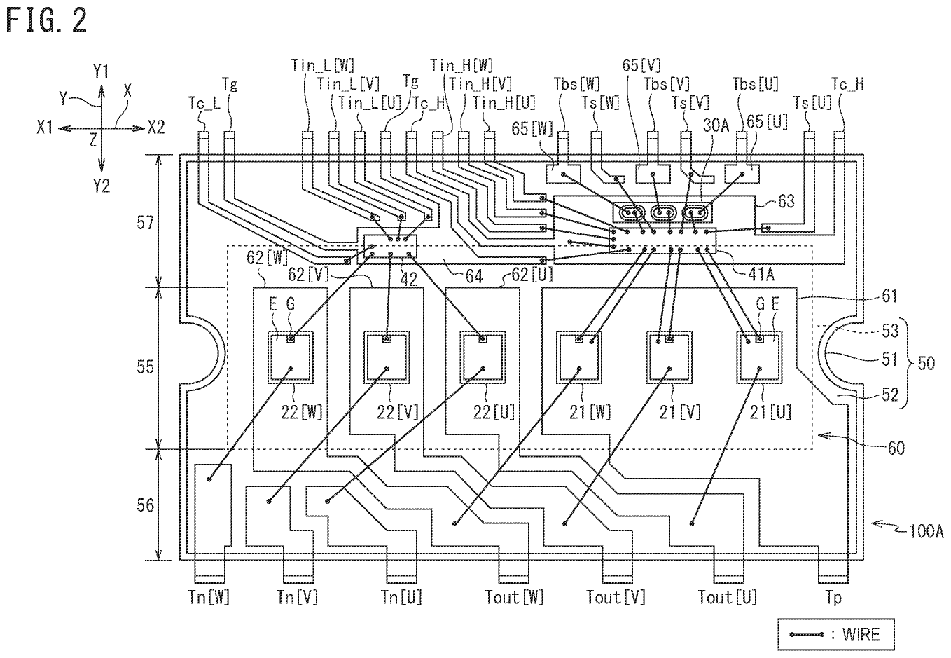

FIG. 2 is a layout diagram illustrative of an arrangement of various types of components included in the semiconductor device 100A according to the first embodiment. In FIG. 2, wires each of which connects predetermined elements to each other are illustrated by straight lines having black dots at both ends. FIG. 3 is a layout diagram illustrative of a vicinity of the semiconductor chip 30A and the high-potential-side control chip 41A included in the semiconductor device 100A in an enlarged manner. FIG. 4 is a cross-sectional view of the semiconductor chip 30A taken along the line V-V illustrated in FIG. 3.

In the following description, as exemplarily illustrated in FIGS. 2 to 4, an X-axis, a Y-axis, and a Z-axis orthogonal to one another are assumed. It is assumed that the longitudinal direction of the semiconductor device 100A (i.e., the long-side direction of a casing 50 (details will be described later) containing respective elements, such as the semiconductor chip 30A and the control chips 41A and 42, and having a thin plate-like rectangular parallelepiped shape) is the X-axis direction. It is also assumed that the lateral direction of the semiconductor device 100A (i.e., the short-side direction of the casing 50) is the Y-axis direction. It is also assumed that the thickness direction (i.e., a direction orthogonal to the long-side direction and the short-side direction of the casing 50) of the semiconductor device 100A is the Z-axis direction. One direction along the X-axis is referred to as an X1 direction, and an opposite direction to the X1 direction is referred to as an X2 direction. Further, one direction along the Y-axis is referred to as a Y1 direction, and an opposite direction to the Y1 direction is referred to as a Y2 direction. Likewise, one direction along the Z-axis is referred to as a Z1 direction, and an opposite direction to the Z1 direction is referred to as a Z2 direction. Further, visually recognizing an arbitrary element of the semiconductor device 100A in a Z-axis direction (the Z1 direction or the Z2 direction) is referred to as “viewed in plan” below.

Note that although when the semiconductor device 100A is actually used, the semiconductor device 100A can be installed in an arbitrary direction, it is assumed in the following description that the Z1 direction is the lower side and the Z2 direction is the upper side for descriptive purposes. Therefore, among arbitrary elements of the semiconductor device 100A, a surface facing the Z1 direction is sometimes referred to as “under surface”, and among the elements, a surface facing the Z2 direction is sometimes referred to as “upper surface”.

As exemplarily illustrated in FIG. 2, the semiconductor device 100A includes the casing 50 to house the respective elements exemplarily illustrated in FIG. 1. The casing 50 includes a resin case 51, a support plate 52, and a sealing resin 53. The resin case 51 is a rectangular frame-shaped structure formed of a resin material. The casing 50 is formed of one of various types of resin materials, such as polyphenylene sulfide (PPS) resin, polybutylene terephthalate (PBT) resin, poly butylene succinate (PBS) resin, polyamide (PA) resin, and acrylonitrile-butadiene-styrene (ABS) resin.

The support plate 52 is a plate-shaped member constituted by laminated layers including an insulating layer (not illustrated) that is formed of a resin material, such as epoxy resin, and a heat dissipation plate (not illustrated) that is formed of a high thermal conductive metallic material, such as aluminum and copper. The insulating layer covers an upper surface of the heat dissipation plate. The heat dissipation plate is a plate-shaped member. The support plate 52 is fixed to the resin case 51 in such a manner as to close an opening of the resin case 51. In a space surrounded by the resin case 51 with the support plate 52 used as a bottom, the three drive chips 21[k] (21[U], 21[V], and 21[W]), the three drive chips 22[k] (22[U], 22[V], and 22[W]), a semiconductor chip 30A, the control chip 41A, and the control chip 42 are accommodated. On the upper surface of each of the drive chips 21[k] and the drive chips 22[k], a main electrode E and a control electrode G are formed, and on the under surface of each of the drive chips 21[k] and the drive chips 22[k], a main electrode C (not illustrated in FIG. 2, see FIG. 1) is formed.

The sealing resin 53 is resin with which a space inside the resin case 51 is filled and seals elements housed in the space. The sealing resin 53 is formed of one of various types of resin materials, such as silicone gel and epoxy resin. Note that the sealing resin 53 may include, in addition to a resin material, one of various types of insulating fillers, such as silicon oxide and aluminum oxide.

In the casing 50, a lead frame 60 is installed. The lead frame 60 is wiring formed of a low-resistance metallic material, such as copper and copper alloy. The lead frame 60 is integrally formed with the resin case 51 by, for example, insert molding. The lead frame 60 is a conductor including a plurality of leads. The aforementioned connection terminals T are ends of the plurality of leads that are exposed to the outside out of the casing 50.

As exemplarily illustrated in FIG. 2, the casing 50 includes an element region 55, a terminal region 56, and a control region 57 as viewed in plan. Each of the element region 55, the terminal region 56, and the control region 57 is a region having a long length along the X-axis. The element region 55 is located between the terminal region 56 and the control region 57.

Some connection terminals T (Tin_H[k], Tin_L[k], Tc_H, Tc_L, Tg, and Tbs[k]) related to operation of the control chip 41A and the control chip 42 among the plurality of connection terminals T are control terminals projecting in the Y1 direction from a side surface of the control region 57 and are arranged along the X-axis at intervals to each other. Further, the connection terminals Ts[k] each of which is electrically connected the main electrode E of a corresponding one of the drive chips 21[k] and connected to the low potential side of a corresponding one of the capacitance elements B[k] and the connection terminal Tc_L that is connected to the voltage terminal Lc of the control chip 42 are also control terminals projecting in the Y1 direction from the side surface of the control region 57 and are arranged along the X-axis at intervals to each other. On the other hand, some connection terminals T (Tout[k], Tp, and Tn[k]) related to power supplied to the motor M among the plurality of connection terminals T are terminals projecting in the Y2 direction from a side surface of the terminal region 56 and are arranged along the X-axis at intervals to each other.

As exemplarily illustrated in FIG. 2, the lead frame 60 includes a die pad 61 and three die pads 62[k]. Each of the die pad 61 and the die pads 62[k] is a metal plate located in the element region 55 as viewed in plan. On the die pad 61, the three drive chips 21[k] are mounted. On each of the die pads 62[k], a corresponding one of the drive chips 22[k] is mounted. For the mounting of the drive chips 21[k] and the drive chips 22[k], a conductive bonding material, such as solder and metal sintered material, is used. As understood from the above description, the three drive chips 21[k] and the three drive chips 22[k] are installed in the element region 55. Note that the three die pads 62[k] may be replaced by a single die pad.

The lead frame 60 includes leads extending from respective ones of the connection terminal Tp, the connection terminals Tout[k], and the connection terminals Tn[k]. The connection terminal Tp is connected to the die pad 61 via a lead (not illustrated). Therefore, the main electrode C (not illustrated in FIG. 2, see FIG. 1) on the under surface of each of the drive chips 21[k] is electrically connected to the connection terminal Tp. Each of the connection terminals Tout[k] is connected to a corresponding one of the die pads 62[k] via a lead (not illustrated). Further, each of the connection terminals Tout[k] is electrically connected to the main electrode E on the upper surface of a corresponding one of the drive chips 21[k] by a wire. Therefore, as exemplarily illustrated in FIG. 1, the main electrode E of each of the drive chips 21[k] and the main electrode C on the under surface of the paired drive chip 22[k] are electrically connected to a corresponding one of the connection terminals Tout[k]. Further, each of the connection terminals Tn[k] is electrically connected to the main electrode E on the upper surface of a corresponding one of the drive chips 22[k] by a wire.

Furthermore, as exemplarily illustrated in FIG. 2, the lead frame 60 includes a die pad 63, a die pad 64, and three connection pads 65[k]. The die pad 63, the die pad 64, and the connection pads 65[k] are metal plates located in the control region 57 as viewed in plan.

The lead frame 60 includes leads extending from connection terminals T for control (Tin_H[k], Tin_L[k], Tc_H, Tc_L, Tg, Tbs[k], and Ts[k]) related to operation of the control chip 41A and the control chip 42. The die pad 63 is connected to the connection terminals Tc_H via leads. Therefore, to the die pad 63, the control voltage Vcc is supplied from the connection terminals Tc_H. The die pad 64 is connected to connection terminals Tg via leads. Therefore, to the die pad 64, the ground voltage is supplied from the connection terminals Tg. Note that the die pad 63 and the connection terminals Tc_H may be integrally formed. The die pad 64 and the connection terminals Tg may be integrally formed.

The control chip 41A is bonded to a front surface of the die pad 63. Although details will be described later, a conductive member (such as bonding material and solder) is used for mounting of the control chip 41A. Therefore, the under surface of the control chip 41A and the die pad 63 are electrically connected to each other. Note that the die pad 63 is an example of a “first conductor”. Note that a portion or all of the die pad 63 and the leads connecting the die pad 63 and the connection terminals Tc_H may be defined as the “first conductor”.

On the upper surface of the control chip 41A, the aforementioned plurality of terminals H are formed (see FIG. 3). Each of the terminals H of the control chip 41A is electrically connected to one of the drive chips 21[k] or one of the connection terminals T by a wire. For example, as exemplarily illustrated in FIGS. 2 and 3, each of the output terminals Hout[k] of the control chip 41A is connected to the control electrode G on the upper surface of a corresponding one of the drive chips 21[k], and each of the middle terminals Hm[k] is connected to the main electrode E on the upper surface of a corresponding one of the drive chips 21[k]. Further, each of the power supply terminals Hs[k] on the upper surface of the control chip 41A is connected to a lead connected to a corresponding one of connection terminals Ts[k]. Each of the middle terminals Hm[k] and a corresponding one of the power supply terminals Hs[k] are electrically connected to each other inside the control chip 41A. The ground terminal Hg on the upper surface of the control chip 41A is connected to a lead connected to the connection terminals Tg. The voltage terminal Hc on the upper surface of the control chip 41A is connected to the die pad 63.

As exemplarily illustrated in FIG. 2, the control chip 42 is bonded to a front surface of the die pad 64. For mounting of the control chip 42, an insulating adhesive agent is used. Therefore, the under surface of the control chip 42 and the die pad 64 are electrically insulated from each other. On the upper surface of the control chip 42, the aforementioned plurality of terminals L (see FIG. 1) are formed. Each of the terminals L of the control chip 42 is electrically connected to one of the drive chips 22[k] or one of the connection terminals T by a wire. For example, each of the output terminals Lout[k] (see FIG. 1) of the control chip 42 is connected to the control electrode G on the upper surface of a corresponding one of the drive chips 22[k]. Further, the voltage terminal Lc (see FIG. 1) is connected to a lead connected to a connection terminal Tc_L, and the ground terminal Lg (see FIG. 1) is connected to leads connected to the connection terminals Tg.

The die pad 63 is connected to the connection terminals Tc_H via leads. Therefore, to the die pad 63, the control voltage Vcc is supplied from the connection terminals Tc_H. The die pad 63 is a conductor for supplying the control voltage Vcc to the voltage terminal Hc of the control chip 41A. The die pad 63, the connection terminals Tc_H, and the leads connecting the die pad 63 and the connection terminals Tc_H may be integrally formed. Note that the die pad 63 is an example of the “first conductor”. Therefore, the semiconductor device 100A includes the die pad 63 (an example of the first conductor) for supplying the control voltage Vcc (an example of a predetermined control voltage) to the voltage terminal Hc (an example of the first terminal). A portion or all of the die pad 63, the connection terminals Tc_H, and leads Rdc (see FIG. 3) connecting the die pad 63 and the connection terminals Tc_H may be defined as the “first conductor”.

Each of the connection pads 65[k] is connected to a corresponding one of the connection terminals Tbs[k] via a lead. The three connection pads 65[k] are arranged along the X-axis at intervals to each other. Specifically, the three connection pads 65[k] are arranged along a peripheral edge located on the Y1 direction side of the casing 50. As described before, to each of the connection terminals Tbs[k], the high potential side of a corresponding one of the capacitance elements B[k] is connected. That is, to each of the connection pads 65[k], a corresponding one of the capacitance elements B[k] is externally connected. Each of the connection pads 65[k], a corresponding one of the connection terminals Tbs[k], and a lead connecting the connection pad 65[k] and the connection terminal Tbs[k] may be integrally formed.

A specific configuration of the semiconductor chip 30A will be described below using FIG. 4 while referring to FIGS. 1 to 3.

As exemplarily illustrated in FIG. 4, the semiconductor chip 30A includes a plurality of (three in the present embodiment) diodes D[k]. The diodes D[k] include a P-type (an example of a first conductivity type) semiconductor substrate 301. Further, the diodes D[k] include a plurality of (three in the present embodiment) N⁻ diffusion layers 302[k] (an example of a second semiconductor layer) that are formed at a predetermined distance. The N⁻ diffusion layers 302[k] form pn junctions in conjunction with the semiconductor substrate 301. In FIG. 4, to facilitate understanding, each of pn junction portions 306[k] that is formed at a junction portion between a body (i.e., a bulk) of the semiconductor substrate 301 and a corresponding one of the N⁻ diffusion layers 302[k] is represented by a schematic symbol of a diode.

The semiconductor substrate 301 forms anode regions of the diodes D[k], and each of the N⁻ diffusion layers 302[k] forms a cathode region of a corresponding one of the diodes D[k].

The semiconductor substrate 301 is formed of, for example, silicon. Each of the N⁻ diffusion layers 302[k] is formed in a predetermined region on a front surface of the semiconductor substrate 301 with a predetermined depth by ion-implanting, for example, phosphorus or arsenic as an N-type impurity and activating a site at which the N-type impurities are ion-implanted.

The pn junction portion 306[U] of the diode D[U] is formed at a junction portion between the body of the semiconductor substrate 301 and the N⁻ diffusion layer 302[U]. The pn junction portion 306[V] of the diode D[V] is formed at a junction portion between the body of the semiconductor substrate 301 and the N⁻ diffusion layer 302[V]. The pn junction portion 306[W] of the diode D[W] is formed at a junction portion between the body of the semiconductor substrate 301 and the N⁻ diffusion layer 302[W].

As exemplarily illustrated in FIG. 4, the semiconductor chip 30A includes a P-type diffusion layer 311 that is formed in an area on the front surface of the semiconductor substrate 301 in which the N⁻ diffusion layers 302[k] are not formed. Therefore, each of the N-diffusion layers 302[k] is formed in an island shape as viewed in plan, and the diffusion layer 311 is formed in the surroundings of the N⁻ diffusion layers 302[k]. Although, in FIG. 4, portions of the diffusion layer 311 at both ends and portions of the diffusion layer 311 on both sides of the N⁻ diffusion layers 302[k] are formed with different widths, the portions may be formed with the same width.

The diffusion layer 311 is formed by ion-implanting, for example, boron as a P-type impurity in a predetermined region on the front surface of the semiconductor substrate 301 and activating a site at which the P-type impurities are ion-implanted. The diffusion layer 311 is, for example, formed with a depth deeper than depths of the N⁻ diffusion layers 302[k].

The diffusion layer 311 has a higher impurity concentration than the N⁻ diffusion layers 302[k]. The diffusion layer 311 is formed between N⁻ diffusion layers 302[k] adjacent to each other. The P-type diffusion layer 311 being formed between N⁻ diffusion layers 302[k] adjacent to each other as described above causes the N-diffusion layers 302[k] to be separated from each other.

As exemplarily illustrated in FIG. 4, the semiconductor chip 30A includes N⁺ diffusion layers 303[k] each of which is formed in a portion of a front surface of a corresponding one of the N⁻ diffusion layers 302[k]. The N⁺ diffusion layers 303[k], for example, have higher impurity concentrations than the N⁻ diffusion layers 302[k] and the diffusion layer 311.

Each of the N⁺ diffusion layers 303[k] is formed with a depth shallower than a depth of a corresponding one of the N⁻ diffusion layers 302[k] by ion-implanting, for example, phosphorus or arsenic as an N-type impurity in a predetermined region on the front surface of the N-diffusion layer 302[k] and activating a site at which the N-type impurities are ion-implanted.

The N⁺ diffusion layer 303[U] is formed in the N-diffusion layer 302[U]. The N⁺ diffusion layer 303[V] is formed in the N⁻ diffusion layer 302[V]. The N⁺ diffusion layer 303[W] is formed in the N⁻ diffusion layer 302[W].

The semiconductor chip 30A includes P⁺ diffusion layers 312a, 312b, 312c, and 312d that are formed in portions of a front surface of the diffusion layer 311. The P⁺ diffusion layers 312a, 312b, 312c, and 312d, for example, have higher impurity concentrations than the diffusion layer 311. The P⁺ diffusion layers 312a, 312b, 312c, and 312d, for example, have the same impurity concentration as the N⁺ diffusion layers 303[k].

The P⁺ diffusion layers 312a, 312b, 312c, and 312d are formed with depths shallower than a depth of the diffusion layer 311 by ion-implanting, for example, boron as a P-type impurity in predetermined regions on the front surface of the diffusion layer 311 and activating sites at which the P-type impurities are ion-implanted.

The P⁺ diffusion layer 312a is formed in a region that is a portion of the front surface of the diffusion layer 311 and is located between a sidewall of the semiconductor substrate 301 and the N⁻ diffusion layer 302[W]. The P⁺ diffusion layer 312b is formed in a region that is a portion of the front surface of the diffusion layer 311 and is located between the N-diffusion layer 302[W] and the N⁻ diffusion layer 302[V]. The P⁺ diffusion layer 312c is formed in a region that is a portion of the front surface of the diffusion layer 311 and is located between the N⁻ diffusion layer 302[V] and the N⁻ diffusion layer 302[U]. The P⁺ diffusion layer 312d is formed in a region that is a portion of the front surface of the diffusion layer 311 and is located between the N⁻ diffusion layer 302[U] and another sidewall of the semiconductor substrate 301.

As exemplarily illustrated in FIG. 4, the semiconductor chip 30A includes cathodes 304[k] each of which is formed on a corresponding one of the N-diffusion layers 302[k] and is electrically connected to a corresponding one of the power supply terminals Hb[k] via a corresponding one of wires Qb[k] (an example of first wirings) (not illustrated in FIG. 4, see FIG. 3). Each of the cathodes 304[k] is formed in contact with a corresponding one of the N⁺ diffusion layers 303[k].

More specifically, each of the cathodes 304[k] includes a conductive plug 304a that is formed in contact with a corresponding one of the N⁺ diffusion layers 303[k] and an electrode pad 304b that is formed in contact with the conductive plug 304a. The conductive plug 304a of the cathode 304[U] is formed in contact with the N⁺ diffusion layer 303[U]. The conductive plug 304a of the cathode 304[V] is formed in contact with the N⁺ diffusion layer 303[V]. The conductive plug 304a of the cathode 304[W] is formed in contact with the N⁺ diffusion layer 303[W]. Thus, each of the cathodes 304[k] and a corresponding one of the N⁺ diffusion layers 303[k] are ohmic-connected. This configuration enables reduction in contact resistance between each of the cathodes 304[k] and a corresponding one of the N⁺ diffusion layers 303[k] to be achieved.

As exemplarily illustrated in FIG. 4, the semiconductor chip 30A includes the anode 305 that is formed on an opposite surface to the front surface of the semiconductor substrate 301, is bonded to the front surface of the die pad 63, and is shared by the plurality of diodes D[k]. The front surface of the semiconductor substrate 301 is a surface facing the Z2 direction, and the opposite surface to the front surface of the semiconductor substrate 301 is a surface facing the Z1 direction. Hereinafter, the opposite surface to the front surface of the semiconductor substrate 301 is referred to as “back surface of the semiconductor substrate 301”. The anode 305 is formed on, for example, the entire back surface of the semiconductor substrate 301. The anode 305 is formed on the back surface of the semiconductor substrate 301 by sputtering or evaporating, for example, aluminum, nickel, or gold. This configuration enables reduction in contact resistance between the semiconductor chip 30A and the die pad 63 to be achieved.

The semiconductor chip 30A is bonded to the front surface of the die pad 63, to which the control voltage Vcc is supplied, using a conductive member 71. As the conductive member 71, for example, an adhesive agent or solder is used. Thus, the body of the semiconductor substrate 301 disposed in the semiconductor chip 30A is electrically connected to the die pad 63 via the conductive member 71. Because of this configuration, to the body of the semiconductor substrate 301 disposed in the semiconductor chip 30A, the control voltage Vcc is supplied via the die pad 63 and the conductive member 71.

As exemplarily illustrated in FIG. 3, the semiconductor chip 30A is installed in such a manner as to cause the conductive member 71 formed on the back surface of the semiconductor chip 30A to face the die pad 63 and overlap the die pad 63. The die pad 63 has a sufficiently larger area than combined area of the semiconductor chip 30A and the control chip 41A. Therefore, the conductive member 71 formed on the semiconductor substrate 301 can be easily connected to the die pad 63.

Returning to FIG. 4, the semiconductor chip 30A includes conductive plugs 313a, 313b, 313c, and 313d that are formed in contact with the P⁺ diffusion layers 312a, 312b, 312c, and 312d, respectively. The conductive plug 313a is formed in contact with the P⁺ diffusion layer 312a. The conductive plug 313b is formed with one end thereof in contact with the P⁺ diffusion layer 312b. The conductive plug 313c is formed with one end thereof in contact with the P⁺ diffusion layer 312c. The conductive plug 313d is formed with one end thereof in contact with the P⁺ diffusion layer 312d. Thus, the P⁺ diffusion layers 312a, 312b, 312c, and 312d and the conductive plugs 313a, 313b, 313c, and 313d are ohmic-connected, respectively.

The semiconductor chip 30A includes an electrode plate 314 that is formed in contact with the other ends of respective ones of the conductive plugs 313a, 313b, 313c, and 313d. The electrode plate 314 has a thin plate-like rectangular parallelepiped shape. The electrode plate 314 has openings into each of which the electrode pad 304b of one of the cathodes 304[k] is inserted at locations at which the cathodes 304[k] are arranged. The electrode pad 304b of each of the cathodes 304[k] is arranged in one of the openings without contact with the electrode plate 314. The electrode plate 314 is formed of, for example, aluminum. Since the P⁺ diffusion layers 312a, 312b, 312c, and 312d and the conductive plugs 313a, 313b, 313c, and 313d are in ohmic contact, respectively, reduction in contact resistances between the electrode plate 314 and the P⁺ diffusion layers 312a, 312b, 312c, and 312d can be achieved.

As exemplarily illustrated in FIG. 4, the semiconductor chip 30A includes a protective film 70 that is formed covering the front surface of the semiconductor chip 30A. The protective film 70 includes an insulating film 701 that is formed in contact with the front surface of the semiconductor substrate 301 and an insulating film 702 that is formed on the insulating film 701. The conductive plugs 313a, 313b, 313c, and 313d and the conductive plugs 304a of the cathodes 304[k] are formed embedded in openings (not illustrated) that are formed in the insulating film 701 in such a manner as to expose portions of the P⁺ diffusion layers 312a, 312b, 312c, and 312d and the N⁺ diffusion layers 303[k]. The insulating film 702 is formed on the electrode plate 314 and the electrode pads 304b of the cathodes 304[k].

The protective film 70 has openings 700[k] each of which exposes a portion of the electrode pad 304b of a corresponding one of the cathodes 304[k]. The opening 700[U] exposes a portion of the electrode pad 304b of the cathode 304[U]. The opening 700[V] exposes a portion of the electrode pad 304b of the cathode 304[V]. The opening 700[W] exposes a portion of the electrode pad 304b of the cathode 304[W].

As exemplarily illustrated in FIG. 3, to the electrode pad 304b of each of the cathodes 304[k], a corresponding one of the wires Qb[k] is connected. Each of the wires Qb[k] is a linear conductor that is formed by wire bonding. Each of the wires Qb[k] includes a wire wiring Qb1 and a wire wiring Qb2.

The wire wiring Qb1 of the wire Qb[U] is a wiring that connects the connection terminal Tbs[U] and the cathode 304[U] of the semiconductor chip 30A. Specifically, one end of the wire wiring Qb1 of the wire Qb[U] is bonded to a front surface of the connection pad 65[U]. The other end of the wire wiring Qb1 of the wire Qb[U] is bonded to a front surface of the electrode pad 304b of the cathode 304[U], which is exposed in the opening 700[U]. Because of this configuration, the connection terminal Tbs[U] and the cathode 304[U] of the semiconductor chip 30A are electrically connected via the connection pad 65[U] and the wire wiring Qb1 of the wire Qb[U].

The wire wiring Qb2 of the wire Qb[U] is a wiring that connects the cathode 304[U] of the semiconductor chip 30A and the power supply terminal Hb[U] of the control chip 41A. Specifically, one end of the wire wiring Qb2 of the wire Qb[U] is bonded to the front surface of the electrode pad 304b of the cathode 304[U], which is exposed in the opening 700[U]. The other end of the wire wiring Qb2 of the wire Qb[U] is bonded to a front surface of the power supply terminal Hb[U] of the control chip 41A. Because of this configuration, the cathode 304[U] of the semiconductor chip 30A and the power supply terminal Hb[U] of the control chip 41A are electrically connected via the wire wiring Qb2 of the wire Qb[U].

The wire wiring Qb1 of the wire Qb[V] is a wiring that connects the connection terminal Tbs[V] and the cathode 304[V] of the semiconductor chip 30A. Specifically, one end of the wire wiring Qb1 of the wire Qb[V] is bonded to a front surface of the connection pad 65[V]. The other end of the wire wiring Qb1 of the wire Qb[V] is bonded to a front surface of the electrode pad 304b of the cathode 304[V], which is exposed in the opening 700[V]. Because of this configuration, the connection terminal Tbs[V] and the cathode 304[V] of the semiconductor chip 30A are electrically connected via the connection pad 65[V] and the wire wiring Qb1 of the wire Qb[V].

The wire wiring Qb2 of the wire Qb[V] is a wiring that connects the cathode 304[V] of the semiconductor chip 30A and the power supply terminal Hb[V] of the control chip 41A. Specifically, one end of the wire wiring Qb2 of the wire Qb[V] is bonded to the front surface of the electrode pad 304b of the cathode 304[V], which is exposed in the opening 700[V]. The other end of the wire wiring Qb2 of the wire Qb[V] is bonded to a front surface of the power supply terminal Hb[V] of the control chip 41A. Because of this configuration, the cathode 304[V] of the semiconductor chip 30A and the power supply terminal Hb[V] of the control chip 41A are electrically connected via the wire wiring Qb2 of the wire Qb[V].

The wire wiring Qb1 of the wire Qb[W] is a wiring that connects the connection terminal Tbs[W] and the cathode 304[W] of the semiconductor chip 30A. Specifically, one end of the wire wiring Qb1 of the wire Qb[W] is bonded to a front surface of the connection pad 65[W]. The other end of the wire wiring Qb1 of the wire Qb[W] is bonded to a front surface of the electrode pad 304b of the cathode 304[W], which is exposed in the opening 700[W]. Because of this configuration, the connection terminal Tbs[W] and the cathode 304[W] of the semiconductor chip 30A are electrically connected via the connection pad 65[W] and the wire wiring Qb1 of the wire Qb[W].

The wire wiring Qb2 of the wire Qb[W] is a wiring that connects the cathode 304[W] of the semiconductor chip 30A and the power supply terminal Hb[W] of the control chip 41A. Specifically, one end of the wire wiring Qb2 of the wire Qb[W] is bonded to the front surface of the electrode pad 304b of the cathode 304[W], which is exposed in the opening 700[W]. The other end of the wire wiring Qb2 of the wire Qb[W] is bonded to a front surface of the power supply terminal Hb[W] of the control chip 41A. Because of this configuration, the cathode 304[W] of the semiconductor chip 30A and the power supply terminal Hb[W] of the control chip 41A are electrically connected via the wire wiring Qb2 of the wire Qb[W].

As described above, the semiconductor device 100A includes the wires Qb[k] (an example of a plurality of first wirings) that are individually connected to the power supply terminals Hb[k] (an example of a plurality of second terminals) and are for supplying the control voltage Vcc to the plurality of power supply terminals Hb[k].

As exemplarily illustrated in FIG. 3, the semiconductor device 100A includes wires Qu, Qv, and Qw that connect input terminals Hin[U], Hin[V], and Hin[W] disposed on the control chip 41A and leads Rd[U], Rd[V], and Rd[W] connected to connection terminal Tin_H[U], Tin_H[V], and Tin_H[W], respectively. The wires Qu, Qv, and Qw are linear conductors that are formed by wire bonding.

The semiconductor device 100A includes a wire Qc that connects the voltage terminal Hc disposed on the control chip 41A and the die pad 63. The wire Qc is a linear conductor that is formed by wire bonding. One end of the wire Qc is bonded to a front surface of the voltage terminal Hc, and the other end of the wire Qc is bonded to the front surface of the die pad 63. Thus, the voltage terminal Hc is connected to to front surface of the die pad 63 via the conductive wire Qc. The die pad 63 is, for example, integrally formed with two leads Rdc. The two leads Rdc are connected to the two connection terminals Tc_H (only one connection terminal Tc_H is illustrated in FIG. 3). Because of this configuration, to the voltage terminal Hc of the control chip 41A, the control voltage Vcc that is input from the connection terminals Tc_H is supplied.

The semiconductor device 100A includes a wire Qdg that connects the ground terminal Hg disposed on the control chip 41A and a lead Rdg connected to the die pad 64 (not illustrated in FIG. 3, see FIG. 2). The wire Qdg is a linear conductor that is formed by wire bonding. Thus, to the ground terminal Hg of the control chip 41A, the ground voltage applied to the die pad 64 is supplied. Because of this configuration, the ground voltages of the control chip 41A and the control chip 42 become the same potential as each other.

The semiconductor device 100A includes wires Qg[U], Qg[V], and Qg[W] that connect the output terminals Hout[U], Hout[V], and Hout[W] disposed on the control chip 41A and the control electrodes G of the drive chips 21[k], respectively. The wires Qg[U], Qg[V], and Qg[W] are linear conductors that are formed by wire bonding.

The semiconductor device 100A includes wires Qe[U], Qe[V], and Qe[W] that connect the middle terminals Hm[U], Hm[V], and Hm[W] disposed on the control chip 41A and the main electrodes E of the drive chips 21[k], respectively. The wires Qe[U], Qe[V], and Qe[W] are linear conductors that are formed by wire bonding.

The semiconductor device 100A includes wires Qs[U], Qs[V], and Qs[W] that connect the power supply terminals Hs[U], Hs[V], and Hs[W] disposed on the control chip 41A and leads Rds[U], Rds[V], and Rds[W] connected to the connection terminal Ts[U], Ts[V], and Ts[W], respectively. The wires Qs[U], Qs[V], and Qs[W] are linear conductors that are formed by wire bonding.

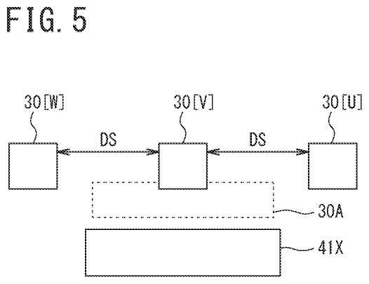

Next, advantageous effects of the semiconductor device 100A will be described using FIG. 5 while referring to FIGS. 1 to 4.

As exemplarily illustrated in FIGS. 1 to 4, the semiconductor chip 30A in the present embodiment has a structure in which the diode D[U] for the bootstrap operation of the U-phase, the diode D[V] for the bootstrap operation of the V-phase, and the diode D[W] for the bootstrap operation of the W-phase are integrated into one chip.

As exemplarily illustrated in FIG. 4, the diode D[U], the diode D[V], and the diode D[W] formed in the semiconductor chip 30A include the pn junction portions 306[U], 306[V], and 306[W] that form pn junctions in the thickness direction of the semiconductor substrate 301 (the Z-axis direction illustrated in FIG. 4), respectively. The P-type semiconductor sides of the pn junction portions 306[U], 306[V], and 306[W] are formed by and share with one another the body of the semiconductor substrate 301. On the other hand, the N-type semiconductor sides of the pn junction portions 306[U], 306[V], and 306[W] are formed by the N⁻ diffusion layers 302[U], 302[V], and 302[W], respectively. The N-diffusion layers 302[U], 302[V], and 302[W] are separated from each other by the P-type diffusion layer 311.

The diffusion layer 311 forms the anode regions of the diodes D[k]. The diode D[U], the diode D[V], and the diode D[W] form pn junctions in conjunction with the N-diffusion layers 302[U], 302[V], and 302[W] in directions parallel with the upper surface of the semiconductor substrate 301 (the X-axis direction illustrated in FIG. 4), respectively.

It is now assumed that the power supply voltage on the high potential side of the external power supply 103 is, for example, 200 V and the control voltage Vcc of the external power supply 104 is, for example, 15 V. Further, a case where the drive chip 21[U], the drive chip 22[V], and the drive chip 22[W] are in the ON state and the drive chip 22[U], the drive chip 21[V], and the drive chip 21[W] are in the OFF state is considered.

In this case, voltage at the connection terminal Tout[U] is 200 V, and 200 V is applied to the cathode 304[U] of the semiconductor chip 30A. Voltages at the connection terminal Tout[V] and the connection terminal Tout[W] are the ground voltage, and the ground voltage is applied to the cathode 304[V] and the cathode 304[W] of the semiconductor chip 30A. Further, 15 V is applied to the semiconductor substrate 301 and the diffusion layer 311.

Thus, the diode D[V] and the diode D[W] charge the capacitance element B[V] and the capacitance element B[W], respectively.

On the other hand, regarding the diode D[U], since reverse bias is applied to the pn junction between the diffusion layer 311 and the N⁻ diffusion layer 302[U] and the pn junction portion 306[U], depletion layers expand from the pn junction and the pn junction portion 306[U] to the diffusion layer 311, the semiconductor substrate 301, and the N⁻ diffusion layer 302[U].

The widths and impurity concentration of the diffusion layer 311 are set in such a manner that the depletion layer expanding in the diffusion layer 311 does not reach the N⁻ diffusion layer 302[V] of the diode D[V] and other depletion layers do not reach the P⁺ diffusion layer 312c, the P⁺ diffusion layer 312d, and the N⁺ diffusion layer 303[U].

By setting the diffusion layer 311 in this way, the N⁻ diffusion layers 302[U], 302[V], and 302[W] are separated from each other by the P-type diffusion layer 311.

The anode 305 connected to the diode D[U], the diode D[V], and diode D[W] is formed on the back surface of the semiconductor substrate 301 and is shared by the diode D[U], the diode D[V], and diode D[W]. On the other hand, the cathodes 304[U], 304[V], and 304[W] that are connected to the diode D[U], the diode D[V], and diode D[W] are formed electrically in contact with the N-diffusion layers 302[U], 302[V], and 302[W], respectively, and are disposed separated from each other.

The semiconductor chip 30A is arranged with the anode 305 electrically connected to the single die pad 63 via the conductive member 71. Thus, to the P-type semiconductor side of respective ones of the pn junction portions 306[k] of the diodes D[k] (i.e., the body of the semiconductor substrate 301), the common control voltage Vcc is supplied via the anode 305, the conductive member 71, the die pad 63, the leads Rdc, and the connection terminals Tc_H (see FIG. 3).

On the other hand, to the N-type semiconductor side of the pn junction portion 306[k] of each of the diodes D[k] (i.e., the N⁻ diffusion layer 302[k]), voltage matching operation of a corresponding one of the drive chips 21[k] is independently supplied via a corresponding one of the N⁺ diffusion layers 303[k], a corresponding one of the cathodes 304[k], the wire wiring Qb2 of a corresponding one of the wires Qb[k], a corresponding one of the connection pads 65[k], and a corresponding one of the connection terminals Tbs[k]. Thus, even when the semiconductor chip 30A has a structure in which the three diodes D[k] for the bootstrap operation of the U-phase, the V-phase, and the W-phase are integrated into one chip, the semiconductor chip 30A is capable of forming a charge route a (see FIG. 1) to charge a capacitance element B[k] in the bootstrap operation with respect to each of the U-phase, the V-phase, and the W-phase.

Furthermore, to the electrode plate 314, the control voltage Vcc is supplied via the die pad 63, the conductive member 71, the anode 305, the semiconductor substrate 301, the diffusion layer 311, the P⁺ diffusion layers 312a, 312b, 312c, and 312d, and the conductive plugs 313a, 313b, 313c, and 313d. Further, the electrode plate 314 exists over boundaries between the N⁻ diffusion layers 302[k] and the diffusion layer 311. Thus, the electrode plate 314 functions as a field plate, as a result of which improvement in withstand voltage of the semiconductor chip 30A can be achieved.

As a configuration of a semiconductor chip having diodes D[k] used for bootstrap operation, a configuration in which an individual semiconductor chip is independently provided with respect to each of the U-phase, the V-phase, and the W-phase is conceivable. FIG. 5 is a layout diagram illustrative of a vicinity of semiconductor chips and high-potential-side drive chips included in a semiconductor device according to a comparative example in an enlarged manner. In FIG. 5, to facilitate understanding, the external shape of the semiconductor chip 30A in the present embodiment is also illustrated. Further, in FIG. 5, a relative position and relative size of the semiconductor chip 30A with respect to a control chip 41X in the comparative example are illustrated in a similar manner to illustration of the relative position and relative size of the semiconductor chip 30A with respect to the control chip 41A in FIGS. 2 and 3.

Each of a semiconductor chip 30[U] for the U-phase, a semiconductor chip 30[V] for the V-phase, and the semiconductor chip 30[W] for the W-phase in the comparative example has a diode for bootstrap (not illustrated). Thus, each of the semiconductor chips 30[U], 30[V], and 30[W] has a smaller size than the semiconductor chip 30A of the present embodiment.

However, as exemplarily illustrated in FIG. 5, when the semiconductor chips 30[U], 30[V], and 30[W] are arranged side by side along the longitudinal direction of the control chip 41X, a predetermined distance DS is required to be maintained between adjacent semiconductor chips among the semiconductor chips 30[U], 30[V], and 30[W]. Thus, an arrangement area of the semiconductor chips 30[U], 30[V], and 30[W] in the comparative example becomes larger than an arrangement area of the semiconductor chip 30A of the present embodiment.

Further, since the semiconductor device according to the comparative example requires three semiconductor chips 30[U], 30[V], and 30[W] for the bootstrap operation, the number of components in the semiconductor device according to the comparative example is larger than that of the semiconductor device 100A according to the present embodiment.

Therefore, compared with the semiconductor device according to the comparative example including the three semiconductor chips 30[U], 30[V], and 30[W] that individually have diodes for bootstrap operation for the U-phase, the V-phase, and the W-phase, respectively, the semiconductor device 100A according to the present embodiment enables space-saving of a mounting area and reduction in the number of components of the semiconductor chip 30A for bootstrap operation to be achieved. Because of this capability, it is possible to achieve a reduction in external dimensions of the semiconductor device 100A.

As described in the foregoing, the semiconductor device 100A according to the present embodiment includes the drive chips 21[k]. The semiconductor device 100A also includes the control chip 41A that includes the plurality of terminals H including the voltage terminal Hc and the power supply terminals Hb[k] and controls each of the drive chips 21[k], using a corresponding one of the power supply voltages Vb[k] supplied to a corresponding one of the power supply terminals Hb[k]. Further, the semiconductor device 100A includes the die pad 63 for supplying the control voltage Vcc to the voltage terminal Hc. Further, the semiconductor device 100A includes the wires Qb[k] each of which is individually connected to a corresponding one of the power supply terminals Hb[k] and is for supplying a corresponding one of power supply voltages Vb[k] to a corresponding one of the power supply terminals Hb[k] and the semiconductor chip 30A that is used for the bootstrap operation to generate the power supply voltages Vb[k] and includes the diodes the number of which is the same as the number of the power supply voltages Vb[k].

Because of this configuration, the semiconductor device 100A is capable of, while suppressing a component cost, achieving miniaturization and cost reduction.

### B: Second Embodiment

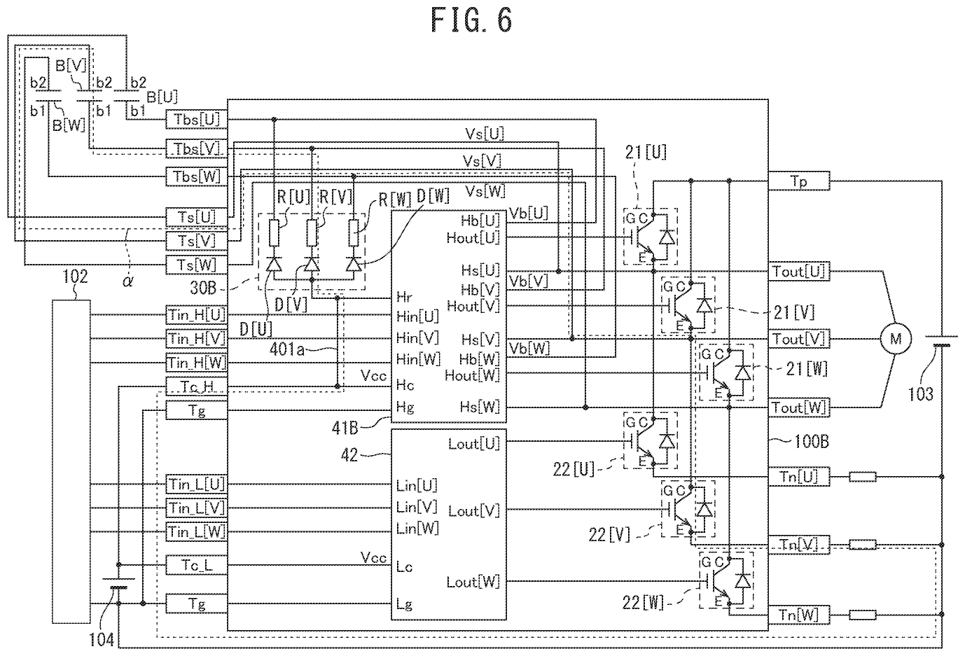

A semiconductor device according to a second embodiment of the present disclosure will be described using FIGS. 6 to 9. Note that in the present embodiment, with respect to elements the functions of which are the same as those of the elements of the semiconductor device according to the first embodiment, reference signs used in the description of the semiconductor device of the first embodiment will also be used for such elements and a detailed description of each of such elements will be appropriately omitted.

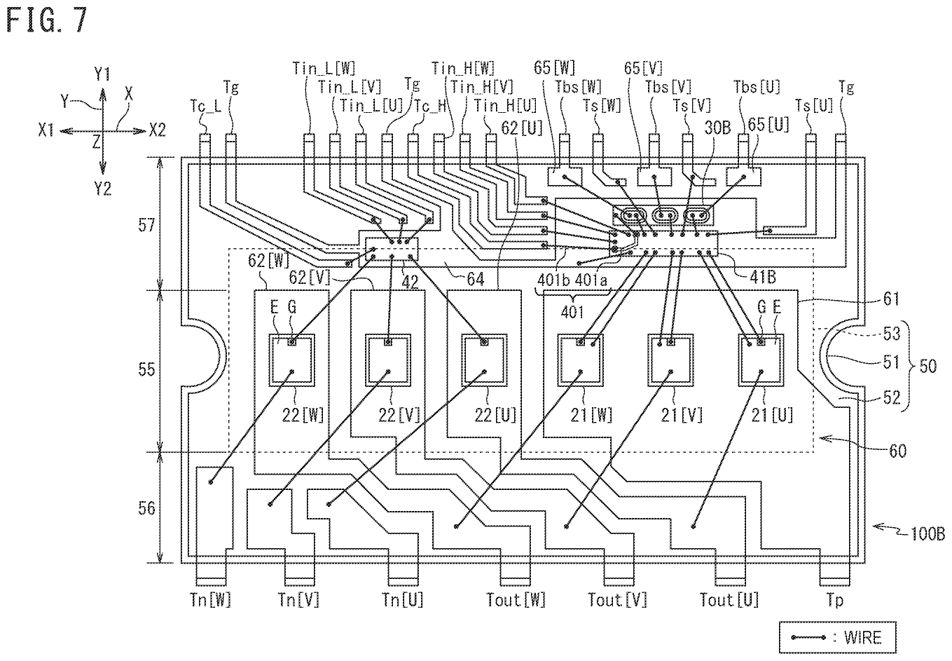

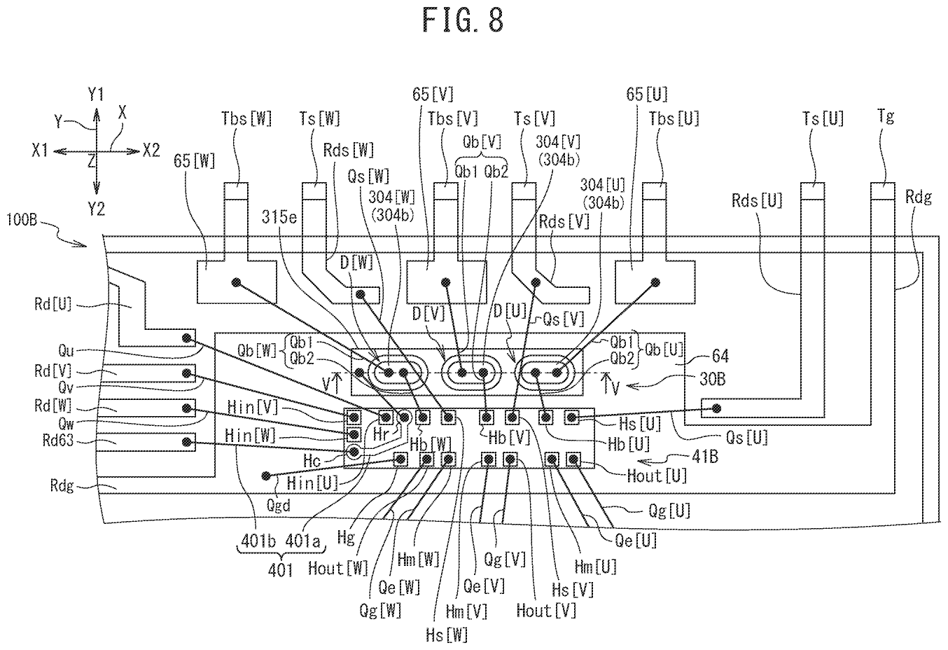

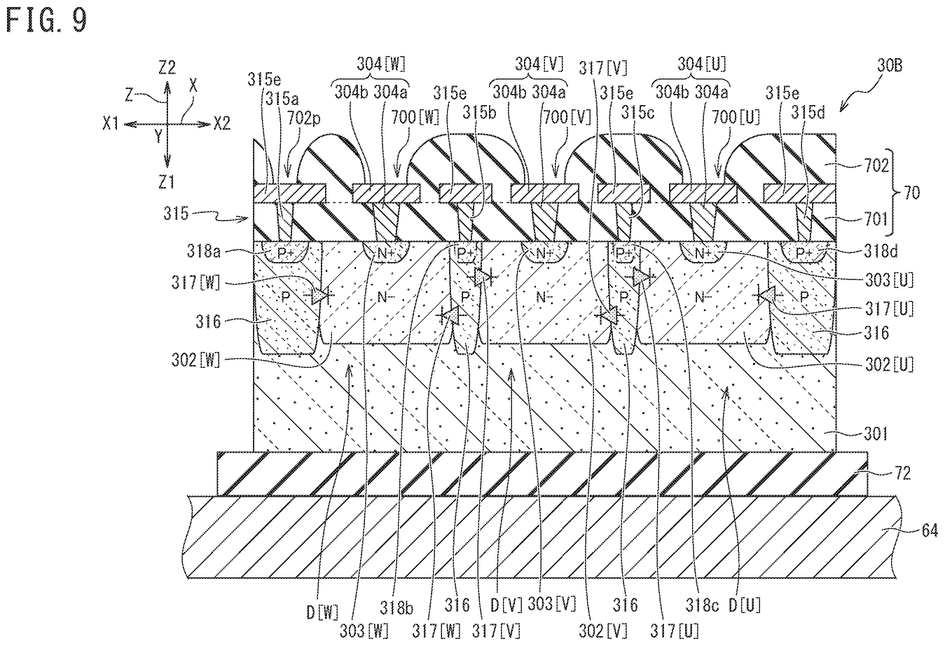

FIG. 6 is a circuit diagram illustrative of an electrical configuration of a semiconductor device 100B according to the present embodiment. FIG. 7 is a layout diagram illustrative of an arrangement of respective elements included in the semiconductor device 100B. FIG. 8 is a layout diagram illustrative of a vicinity of a semiconductor chip 30B and high-potential-side drive chips 21[k] included in the semiconductor device 100B in an enlarged manner. FIG. 9 is a diagram illustrative of the semiconductor chip 30B included in the semiconductor device 100B and is a cross-sectional view of the semiconductor chip 30B taken along the line V-V illustrated in FIG. 8. The semiconductor device 100B according to the present embodiment has a feature that the semiconductor device 100B includes a plurality of diodes D[k] used for bootstrap operation and charge routes are formed in directions orthogonal to the thickness direction of a semiconductor substrate 301.

As exemplarily illustrated in FIG. 6, the semiconductor device 100B according to the present embodiment includes the drive chips 21[k] (an example of a plurality of power semiconductor elements). The semiconductor device 100B includes a control chip 41B that includes a plurality of terminals H including a voltage terminal Hc (an example of a first terminal) and power supply terminals Hb[k] (an example of a plurality of second terminals) and controls each of the drive chips 21[k], using a corresponding one of power supply voltages Vb[k] supplied to a corresponding one of the power supply terminals Hb[k]. The semiconductor device 100B includes a lead Rd63 (an example of a first conductor, not illustrated in FIG. 6, see FIG. 8) for supplying control voltage Vcc to the voltage terminal Hc. The semiconductor device 100B includes wires Qb[k] (an example of a plurality of first wirings, not illustrated in FIG. 6, see FIG. 8) each of which is individually connected to a corresponding one the power supply terminals Hb[k] and is for supplying a corresponding one of the power supply voltages Vb[k] to the power supply terminal Hb[k]. The semiconductor device 100B includes the semiconductor chip 30B that is used for bootstrap operation to generate the power supply voltages Vb[k] and includes the diodes D[k] the number of which is the same as the number of the power supply voltages Vb[k].

The control chip 41B in the present embodiment differs from the control chip 41A in the first embodiment in including a relay terminal Hr. The relay terminal Hr is connected to the voltage terminal Hc by a relay pattern 401a. Details of the relay terminal Hr will be described later.

As exemplarily illustrated in FIG. 7, a die pad 64 disposed in the semiconductor device 100B is formed in such a manner as to spread beneath the control chips 41B and 42 and the semiconductor chip 30B. The control chips 41B and 42 and the semiconductor chip 30B are bonded on the die pad 64 (an example of a second conductor). That is, the control chips 41B and 42 and the semiconductor chip 30B are bonded to a front surface of the die pad 64. For mounting of the control chips 41B and 42 and the semiconductor chip 30B, an insulating adhesive agent is used. Therefore, under surfaces of the control chips 41B and 42 and the semiconductor chip 30B and the die pad 64 are electrically insulated from each other.

As exemplarily illustrated in FIGS. 7 and 8, the semiconductor device 100B includes a wiring member 401 (an example of a second wiring) connected to the lead Rd63. The control chip 41B includes in the terminals H the relay terminal Hr that is electrically connected to an anode 315 (details will be described later). The wiring member 401 includes the relay pattern 401a and a wire 401b. Therefore, the wiring member 401 includes the relay pattern 401a that connects the relay terminal Hr and the voltage terminal Hc.

Next, a specific configuration of the semiconductor chip 30B will be described using FIG. 9 while referring to FIGS. 6 to 8.

As exemplarily illustrated in FIG. 9, the semiconductor chip 30B includes a plurality of (three in the present embodiment) diodes D[k]. The diodes D[k] include a P-type (an example of a first conductivity type) semiconductor substrate 301. Each of the diodes D[k] includes a corresponding one of N-type (an example of a second conductivity type) N⁻ diffusion layers 302[k] (an example of a plurality of second semiconductor layers) that are formed side by side at a predetermined distance on a front surface layer of the semiconductor substrate 301. The diodes D[k] include a P-type (an example of the first conductivity type) diffusion layer 316 (an example of the first semiconductor layer) that is formed in an area on the front surface layer of the semiconductor substrate 301 in which the N⁻ diffusion layers 302[k] are not formed. In FIG. 9, to facilitate understanding, pn junction portions 317[k] each of which is formed at a junction portion between a corresponding one of the N⁻ diffusion layers 302[k] and the diffusion layer 316 are illustrated by schematic symbols of diodes.

The diffusion layer 316 forms anode regions of the diodes D[k], and each of the N⁻ diffusion layers 302[k] forms a cathode region of a corresponding one of the diodes D[k]. Note that each of the N⁻ diffusion layers 302[k] also serves as a corresponding one of resistance elements R[k]. Although the semiconductor substrate 301 also functions as the anode regions of the diodes D[k], portions through which current mainly flows are the junction portions between the N⁻ diffusion layers 302[k] and the diffusion layer 316.

The pn junction portion 317[U] of the diode D[U] is formed at a junction portion between the diffusion layer 316 and the N⁻ diffusion layer 302[U]. The pn junction portion 317[V] of the diode D[V] is formed at a junction portion between the N⁻ diffusion layer 302[V] and the diffusion layer 316. The pn junction portion 317[W] of the diode D[W] is formed at a junction portion between the N⁻ diffusion layer 302[W] and the diffusion layer 316.

As exemplarily illustrated in FIG. 9, the semiconductor chip 30B includes the P-type diffusion layer 316 that is formed in an area on the front surface layer of the semiconductor substrate 301 in which the N-diffusion layers 302[k] are not formed. Therefore, each of the N⁻ diffusion layers 302[k] is formed in an island shape as viewed in plan, and the diffusion layer 316 is formed in the surroundings of the N⁻ diffusion layers 302[k]. Although, in FIG. 9, portions of the diffusion layer 316 at both ends and portions of the diffusion layer 316 on both sides of the N⁻ diffusion layers 302[k] are formed with different widths, the portions may be formed with the same width.

The diffusion layer 316 is formed by ion-implanting, for example, boron as a P-type impurity in a predetermined region on the front surface of the semiconductor substrate 301 and activating a site at which the P-type impurities are ion-implanted. The diffusion layer 316 is, for example, formed with a depth deeper than depths of the N⁻ diffusion layers 302[k].

The semiconductor chip 30B includes P⁺ diffusion layers 318a, 318b, 318c, and 318d that are formed in portions of a front surface of the diffusion layer 316. The P⁺ diffusion layers 318a, 318b, 318c, and 318d have higher impurity concentrations than the diffusion layer 316. The P⁺ diffusion layers 318a, 318b, 318c, and 318d, for example, have the same impurity concentration as N⁺ diffusion layers 303[k].

The P⁺ diffusion layers 318a, 318b, 318c, and 318d are formed with depths shallower than a depth of the diffusion layer 316 in predetermined regions on the front surface of the diffusion layer 316 by ion-implanting, for example, boron as a P-type impurity and activating sites at which the P-type impurities are ion-implanted.

The P⁺ diffusion layer 318a is formed in a region that is a portion of the front surface of the diffusion layer 316 and is located between a sidewall of the semiconductor substrate 301 and the N⁻ diffusion layer 302[W]. The P⁺ diffusion layer 318b is formed in a region that is a portion of the front surface of the diffusion layer 316 and is located between the N-diffusion layer 302[W] and the N⁻ diffusion layer 302[V]. The P⁺ diffusion layer 318c is formed in a region that is a portion of the front surface of the diffusion layer 316 and is located between the N⁻ diffusion layer 302[V] and the N⁻ diffusion layer 302[U]. The P⁺ diffusion layer 318d is formed in a region that is a portion of the front surface of the diffusion layer 316 and is located between the N⁻ diffusion layer 302[U] and another sidewall of the semiconductor substrate 301.

As exemplarily illustrated in FIG. 9, the semiconductor chip 30B includes cathodes 304[k] each of which is formed on a corresponding one of the N-diffusion layers 302[k] and is electrically connected to a corresponding one of the power supply terminals Hb[k] via a corresponding one of wires Qb[k] (an example of the first wirings) (not illustrated in FIG. 9, see FIG. 8). Each of the cathodes 304[k] is formed in contact with a corresponding one of the N⁻ diffusion layers 303[k].

Since the cathodes 304[k] in the present embodiment have the same configurations as the cathodes 304[k] in the first embodiment, a description thereof will be omitted. Each of the cathodes 304[k] is formed with the conductive plug 304a in contact with a corresponding one of the N⁺ diffusion layers 303[k]. Thus, each of the cathodes 304[k] and a corresponding one of the N⁺ diffusion layers 303[k] are ohmic-connected. This configuration also enables reduction in contact resistance between each of the cathodes 304[k] and a corresponding one of the N⁺ diffusion layers 303[k] in the present embodiment.

As exemplarily illustrated in FIG. 9, the semiconductor chip 30B includes the anode 315 that is formed on the diffusion layer 316 and is electrically connected the lead Rd63 (not illustrated in FIG. 9, see FIG. 8) via the wiring member 401 (not illustrated in FIG. 9, see FIG. 8).

More specifically, the anode 315 includes conductive plugs 315a, 315b, 315c, and 315d that are formed in contact with the P⁺ diffusion layers 318a, 318b, 318c, and 318d, respectively, and an electrode plate 315e that is formed in contact with the conductive plugs 315a, 315b, 315c, and 315d. The conductive plug 315a is formed in contact with the P⁺ diffusion layer 318a. The conductive plug 315b is formed in contact with the P⁺ diffusion layer 318b. The conductive plug 315c is formed in contact with the P⁺ diffusion layer 318c. The conductive plug 315d is formed in contact with the P⁺ diffusion layer 318d. Thus, the anode 315 and the P⁺ diffusion layers 318a, 318b, 318c, and 318d are ohmic-connected. This configuration enables reduction in contact resistance between the anode 315 and the P⁺ diffusion layers 318a, 318b, 318c, and 318d to be achieved.

The electrode plate 315e has a thin plate-like rectangular parallelepiped shape. The electrode plate 315e has openings into each of which an electrode pad 304b of one of the cathodes 304[k] is inserted at locations at which the cathodes 304[k] are arranged. The electrode pad 304b of each of the cathodes 304[k] is arranged in one of the openings without contact with the electrode plate 315e. The electrode plate 315e is formed of, for example, aluminum.

As exemplarily illustrated in FIG. 8, the electrode plate 315e is electrically connected to the relay terminal Hr of the control chip 41B by a wire Q315. One end of the wire Q315 is bonded to a portion of a front surface of the electrode plate 315e that is exposed in an opening 702p (see FIG. 9) formed in a protective film 70 (not illustrated in FIG. 8, see FIG. 9). The other end of the wire Q315 is bonded to a front surface of the relay terminal Hr. The relay terminal Hr is formed at one end of the relay pattern 401a. At the other end of the relay pattern 401a, the voltage terminal Hc is formed. The voltage terminal Hc and the lead Rd63 are connected to each other by the wire 401b. The lead Rd63 is connected to a connection terminal Tc_H (see FIG. 7) to which the control voltage Vcc is input from an external power supply 104 (see FIG. 6). Thus, to the anode 315, the control voltage Vcc is supplied via the connection terminal Tc_H, the lead Rd63, the wiring member 401 (i.e., the wire 401b and the relay pattern 401a), and the wire Q315.

Returning to FIG. 9, the semiconductor chip 30B has a surface on the opposite side to the front surface of the semiconductor substrate 301 (i.e., the back surface) adhered to the die pad 64 by an insulating adhesive agent 72. Although details will be described later, to a body of the semiconductor substrate 301 of the semiconductor chip 30B, the control voltage Vcc is supplied from the anode 315. On the other hand, the die pad 64 is connected to connection terminals Tg to which a ground voltage is supplied via leads Rdg. Thus, to the die pad 64, the ground voltage is supplied via the connection terminals Tg and the leads Rdg.

Therefore, voltage supplied to the semiconductor substrate 301 of the semiconductor chip 30B and voltage supplied to the die pad 64 are different from each other. However, since the semiconductor substrate 301 of the semiconductor chip 30B and the die pad 64 are insulated from each other by the insulating adhesive agent 72, the connection terminal Tc_H and the connection terminals Tg are prevented from being short-circuited.

A ground terminal Hg disposed on the control chip 41B is connected to the die pad 64 via a wire Qgd. Specifically, one end of the wire Qgd is bonded to a front surface of the ground terminal Hg of the control chip 41B, and the other end of the wire Qgd is bonded to the front surface of the die pad 64. Because of this configuration, to the ground terminal Hg of the control chip 41B, the ground voltage is supplied via the connection terminals Tg, the die pad 64, and the wire Qgd.

Next, advantageous effects of the semiconductor device 100B will be described using FIGS. 6 to 9.

As exemplarily illustrated in FIGS. 6 to 9, the semiconductor chip 30B in the present embodiment has a structure in which the diode D[U] for the bootstrap operation of the U-phase, the diode D[V] for the bootstrap operation of the V-phase, and the diode D[W] for the bootstrap operation of the W-phase are integrated into one chip.

As exemplarily illustrated in FIG. 9, the diode D[U], the diode D[V], and the diode D[W] formed in the semiconductor chip 30B include the pn junction portions 317[U], 317[V], and 317[W] that form pn junctions in directions orthogonal to the thickness direction of the semiconductor substrate 301 (the X-axis direction illustrated in FIG. 9), respectively. The P-type semiconductor sides of the pn junction portions 317[U], 317[V], and 317[W] are formed by and share with one another the diffusion layer 316. On the other hand, the N-type semiconductor sides of the pn junction portions 317[U], 317[V], and 317[W] are formed by the N⁻ diffusion layers 302[U], 302[V], and 302[W], respectively. The N-diffusion layers 302[U], 302[V], and 302[W] are separated from each other by the P-type diffusion layer 316.

The anode 315 connected to the diode D[U], the diode D[V], and diode D[W] is arranged above the semiconductor substrate 301 and is shared by the diode D[U], the diode D[V], and diode D[W]. On the other hand, the cathodes 304[U], 304[V], and 304[W] that are connected to the diode D[U], the diode D[V], and diode D[W] are formed in contact with the N⁻ diffusion layers 302[U], 302[V], and 302[W], respectively, and are disposed separated from each other.

The diffusion layer 316 forms the anode regions of the diodes D[k]. The diode D[U] forms the pn junction portion 317[U] in conjunction with the N⁻ diffusion layer 302[U] and a portion of the diffusion layer 316 arranged around the N⁻ diffusion layer 302[U]. The diode D[V] forms the pn junction portion 317[V] in conjunction with the N⁻ diffusion layer 302[V] and a portion of the diffusion layer 316 arranged around the N⁻ diffusion layer 302[V]. The diode D[W] forms the pn junction portion 317[W] in conjunction with the N⁻ diffusion layer 302[W] and a portion of the diffusion layer 316 arranged around the N⁻ diffusion layer 302[W]. Further, the diode D[U], the diode D[V], and the diode D[W] form pn junctions in conjunction with the N⁻ diffusion layers 302[U], 302[V], and 302[W] in the thickness direction of the semiconductor substrate 301 (the Z-axis direction illustrated in FIG. 9), respectively.

It is now assumed that the power supply voltage on the high potential side of the external power supply 103 is, for example, 200 V and the control voltage Vcc of the external power supply 104 is, for example, 15 V. Further, a case where the drive chip 21[U], the drive chip 22[V], and the drive chip 22[W] are in the ON state and the drive chip 22[U], the drive chip 21[V], and the drive chip 21[W] are in the OFF state is considered.

In this case, voltage at a connection terminal Tout[U] is 200 V, and 200 V is applied to the cathode 304[U] of the semiconductor chip 30B. Voltages at a connection terminal Tout[V] and a connection terminal Tout[W] are the ground voltage, and the ground voltage is applied to the cathode 304[V] and the cathode 304[W] of the semiconductor chip 30B. Further, 15 V is applied to the semiconductor substrate 301 and the diffusion layer 316.

Thus, the diode D[V] and the diode D[W] charge a capacitance element B[V] and a capacitance element B[W], respectively.

On the other hand, regarding the diode D[U], since reverse bias is applied to the pn junction between the semiconductor substrate 301 and the N⁻ diffusion layer 302[U] and the pn junction portion 317[U], depletion layers expand from the pn junction and the pn junction portion 317[U] to a portion of the diffusion layer 316 arranged around the N⁻ diffusion layer 302[U], the semiconductor substrate 301, and the N⁻ diffusion layer 302[U].

The widths and impurity concentration of the diffusion layer 316 are set in such a manner that the depletion layer expanding in a portion of the diffusion layer 316 around the N⁻ diffusion layer 302[U] does not reach the N⁻ diffusion layer 302[V] of the diode D[V] and other depletion layers do not reach the P⁺ diffusion layer 318c, the P⁺ diffusion layer 318d, and the N⁺ diffusion layer 303[U].

By setting the diffusion layer 316 in this way, the N⁻ diffusion layers 302[U], 302[V], and 302[W] are separated from each other by the P-type diffusion layer 316.

To the P-type semiconductor side of the pn junction portion 306[k] of each of the diodes D[k] (i.e., the diffusion layer 316), the common control voltage Vcc is supplied via the anode 315, the wire Q315, the wiring member 401, the conductive member 71, the lead Rd63, and the connection terminal Tc_H (see FIG. 7).

On the other hand, to the N-type semiconductor side of the pn junction portion 317[k] of each of the diodes D[k] (i.e., the N⁻ diffusion layer 302[k]), voltage matching the bootstrap operation is independently supplied via a corresponding one of the N⁺ diffusion layers 303[k], a corresponding one of the cathodes 304[k], the wire wiring Qb2 of a corresponding one of the wires Qb[k], a corresponding one of connection pads 65[k], and a corresponding one of connection terminals Tbs[k]. Thus, even when the semiconductor chip 30B has a structure in which the three diodes D[k] for the bootstrap operation of the U-phase, the V-phase, and the W-phase are integrated into one chip, the semiconductor chip 30B is capable of forming a charge route a (see FIG. 6) to charge a capacitance element B[k] in the bootstrap operation with respect to each of the U-phase, the V-phase, and the W-phase.

Further, to the electrode plate 315e, the control voltage Vcc is supplied. Further, the electrode plate 315e also exists over boundaries between the N⁻ diffusion layers 302[k] and the diffusion layer 316. Thus, the electrode plate 315e functions as a field plate, as a result of which improvement in withstand voltage of the semiconductor chip 30B can be achieved.

As described above, since the semiconductor device 100B according to the present embodiment includes the semiconductor chip 30B in which the three diodes D[k] for bootstrap operation are integrated into one chip, compared with the semiconductor device according to the comparative example (see FIG. 5) including the three semiconductor chips 30[U], 30[V], and 30[W] that individually have diodes for bootstrap operation for the U-phase, the V-phase, and the W-phase, respectively, the semiconductor device 100B enables space-saving of a mounting area and reduction in the number of components of the semiconductor chip 30B for bootstrap operation to be achieved. Because of this capability, it is possible to achieve a reduction in external dimensions of the semiconductor device 100B.

As described in the foregoing, the semiconductor device 100B according to the present embodiment includes the drive chips 21[k], the control chip 41A that includes the plurality of terminals H including the voltage terminal Hc and the power supply terminals Hb[k] and is configured to control each of the drive chips 21[k], using a corresponding one of the power supply voltages Vb[k] supplied to a corresponding one of the power supply terminals Hb[k], the lead Rd63 for supplying the control voltage Vcc to the voltage terminal Hc, the wires Qb[k] each of which is individually connected to a corresponding one of the power supply terminals Hb[k] and is for supplying a corresponding one of the power supply voltages Vb[k] to a corresponding one of the power supply terminals Hb[k], and the semiconductor chip 30B that is used for the bootstrap operation to generate the power supply voltages Vb[k] and includes the diodes D[k] the number of which is the same as the number of the power supply voltages Vb[k].

Because of this configuration, the semiconductor device 100B is capable of, while suppressing a component cost, achieving miniaturization and cost reduction.

### REFERENCE SIGNS LIST

21, 22 Drive chip
30[U], 30[V], 30[W], 30A, 30B Semiconductor chip
41A, 41B, 41X, 42 Control chip
50 Casing
51 Resin case
52 Support plate
53 Sealing resin
55 Element region
56 Terminal region
57 Control region
60 Lead frame
61, 62, 63, 64 Die pad
65[k] (k=U, V, or W) Connection pad
70 Protective film
71 Conductive member
72 Insulating adhesive agent
100A, 100B Semiconductor device
102 Control device
103, 104 External power supply
301 Semiconductor substrate
302[k] (k=U, V, or W) N⁻ diffusion layer
303[k] (k=U, V, or W) N⁺ diffusion layer
304a, 313a, 313b, 313c, 313d, 315a, 315b, 315c, 315d Conductive plug
304b Electrode pad
305, 315 Anode
306[k] (k=U, V, or W), 317[k] (k=U, V, or W) pn junction portion
311, 316 Diffusion layer
312a, 312b, 312c, 312d, 318a, 318b, 318c, 318d P⁺ diffusion layer
314, 315e Electrode plate
401 Wiring member
401a Relay pattern
401b Wire
700[k] (k=U, V, or W), 702p Opening
701, 702 Insulating film
B Capacitance element
b1 First electrode
b2 Second electrode
C, E Main electrode
D Diode
DS Distance
G Control electrode
H, L Terminal
Hb Power supply terminal
Hc, Lc Voltage terminal
Hg, Lg Ground terminal
Hin Input terminal
Hm[k] (k=U, V, or W) Middle terminal
Hout[k] (k=U, V, or W) Output terminal
Hr Relay terminal
Hs[k] (k=U, V, or W) Power supply terminal
Lin[k] (k=U, V, or W) Input terminal
Lout[k] (k=U, V, or W) Output terminal
M Motor
Q315, Qb[k] (k=U, V, or W), Qc, Qdg, Qe, Qg, Qgd, Qs, Qu,
Qv, Qw Wire
Qb1, Qb2 Wire wiring
Rs[k] (k=U, V, or W) Resistance element
Rd[k] (k=U, V, or W), Rd63, Rdc, Rdg, Rds[k] (k=U, V, or W) Lead
T, Tbs[k] (k=U, V, or W), Tc_H, Tc_L, Tg, Tin_H[k] (k=U, V, or W), Tin_L[k] (k=U, V, or W), Tn[k] (k=U, V, or W),
Tout[k] (k=U, V, or W), Tp, Ts[k] (k=U, V, or W) Connection terminal
Vb[k] (k=U, V, or W) Power supply voltage
Vcc Control voltage
Vs Power supply voltage
α Charge route

1. A semiconductor device comprising:
a plurality of power semiconductor elements;
a control chip including a plurality of terminals including a first terminal and a plurality of second terminals and configured to control each of the plurality of power semiconductor elements, using a corresponding one of power supply voltages supplied to a corresponding one of the plurality of second terminals;
a first conductor configured to supply a predetermined control voltage to the first terminal;
a plurality of first wirings each connected to a corresponding one of the plurality of second terminals and configured to supply a corresponding one of the power supply voltages to a corresponding one of the plurality of second terminals; and
a semiconductor chip used for bootstrap operation to generate the power supply voltages and including diodes a number of which is same as a number of the second terminals.

2. The semiconductor device according to claim 1, wherein
the semiconductor chip includes:
a semiconductor substrate of a first conductivity type forming anode regions of a plurality of the diodes; and
a plurality of second semiconductor layers of a second conductivity type forming cathode regions of a plurality of the diodes and formed side by side at a predetermined distance in a front surface layer of the semiconductor substrate.

3. The semiconductor device according to claim 2, wherein
the semiconductor chip includes:
an anode formed on an opposite surface to the front surface layer of the semiconductor substrate, bonded to a front surface of the first conductor, and shared by a plurality of the diodes; and
a cathode formed on each of the plurality of second semiconductor layers and electrically connected to a corresponding one of the second terminals via a corresponding one of the first wirings.

4. The semiconductor device according to claim 3, wherein the first terminal is connected to the front surface of the first conductor via a conductive wire.

5. The semiconductor device according to claim 1 further comprising
a second wiring connected to the first conductor,
wherein the semiconductor chip includes:
a semiconductor substrate of a first conductivity type;
a plurality of second semiconductor layers of a second conductivity type forming cathode regions of a plurality of the diodes and formed side by side at a predetermined distance in a front surface layer of the semiconductor substrate; and
a first semiconductor layer of a first conductivity type forming anode regions of a plurality of the diodes and formed in an area in a front surface layer of the semiconductor substrate in which the plurality of second semiconductor layers are not formed.

6. The semiconductor device according to claim 5, wherein
the semiconductor chip includes:
an anode formed on the first semiconductor layer and electrically connected to the first conductor via the second wiring; and
a cathode formed on each of the plurality of second semiconductor layers and electrically connected to a corresponding one of the second terminals via a corresponding one of the first wirings.

7. The semiconductor device according to claim 6, wherein
the control chip includes a relay terminal electrically connected to the anode in the plurality of terminals, and
the second wiring includes a relay pattern connecting the relay terminal and the first terminal.

8. The semiconductor device according to claim 5, wherein the control chip and the semiconductor chip are bonded on a second conductor.

9. The semiconductor device according to claim 6, wherein the control chip and the semiconductor chip are bonded on a second conductor.

10. The semiconductor device according to claim 7, wherein the control chip and the semiconductor chip are bonded on a second conductor.
